(19) United States
(12) Patent Application Publication
(10) Pub. No.: US 2013/0153413 A1
(43) Pub. Date: Jun. 20, 2013

(54) SPUTTER GUN SHUTTER

(71) Applicants: Hong Sheng Yang, Pleasanton, CA (US); Hien Min Huu Le, San Jose, CA (US); Xuena Zhang, San Jose, CA (US)

(72) Inventors: Hong Sheng Yang, Pleasanton, CA (US); Hien Min Huu Le, San Jose, CA (US); Xuena Zhang, San Jose, CA (US)

(73) Assignee: Intermolecular, Inc., San Jose, CA (US)

(21) Appl. No.: 13/327,281

(22) Filed: Dec. 15, 2011

(51) Int. Cl. C23C 14/34; C23C 14/35

(52) U.S. Cl. 204/298.11

(57) ABSTRACT

In some embodiments of the present invention, a gun shutter is provided that comprises a gun shutter lip that aligns with a grounded shield lip to form a gap. The gap is operable to prevent contamination from other sputter guns present in the chamber. Additionally, the gun shutter is spaced apart from the face of the target so that a stable plasma may be ignited and maintained between the face of the target and the gun shutter. This allows the gun shutter to be used as a burn-in or conditioning shield and allows the elimination of other shields, thus lowering the size, complexity, and cost of the chamber.

### FIELD OF THE INVENTION

The present invention relates generally to the sputter deposition of materials in a multi-source sputtering chamber.

### BACKGROUND OF THE INVENTION

Physical vapor deposition is commonly used within the semiconductor industry, as well as within solar, glass coating, and other industries, in order to deposit a layer over a substrate. Sputtering is a common physical vapor deposition method, where atoms or molecules are ejected from a target material by high-energy particle bombardment and then deposited onto the substrate.

The manufacture of integrated circuits (IC), semiconductor devices, flat panel displays, optoelectronics devices, data storage devices, magneto-electronic devices, magneto-optic devices, packaged devices, and the like entails the integration and sequencing of many unit processing steps. As an example, IC manufacturing typically includes a series of processing steps such as cleaning, surface preparation, deposition, lithography, patterning, etching, planarization, implantation, thermal annealing, and other related unit processing steps. The precise sequencing and integration of the unit processing steps enables the formation of functional devices meeting desired performance metrics such as speed, power consumption, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

Sputtering systems used for combinatorial processing typically comprise a plurality of sputter guns. Typically, the sputter guns are operable to deposit different materials by sputtering a target mounted on each gun. Each sputter gun will either have a gun shutter or be retracted from the deposition chamber to protect the face of the target from contamination from other sputter guns present in the chamber. Typical gun shutters comprise a flat metal plate spaced close to the target face. Sputter guns must be subjected to a burn-in or conditioning process to properly clean or condition the face of the target. The material that is sputtered from the target during the burn-in or conditioning process must be captured on a shutter or burin-in substrate. The conventional gun shutter is too close to the face of the target to sustain a stable plasma if a plasma could be ignited. The close distance would also prevent plasma being ignited or require a higher pressure to ignite the plasma. Therefore, typically, a second shield or substrate shutter is required to be designed and incorporated into the chamber design to address the burn-in and conditioning process. This adds size, complexity, and cost of the chamber.

Therefore, there is a need for a gun shutter that protects the face of the target from contamination from other sputter guns present in the chamber and also allows the gun shutter to be used as a burn-in or conditioning shield.

### SUMMARY OF THE DISCLOSURE

In some embodiments of the present invention, a gun shutter is provided that comprises a gun shutter lip that aligns with a grounded shield lip to form a gap. The gap is operable to prevent contamination from other sputter guns present in the chamber. Additionally, the gun shutter is spaced apart from the face of the target so that a stable plasma may be ignited and maintained between the face of the target and the gun shutter. This allows the gun shutter to be used as a burn-in or conditioning shield and allows the elimination of other shields, thus lowering the size, complexity, and cost of the chamber.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with some embodiments of the present invention.

FIG. 3 is a simplified schematic diagram illustrating an integrated high productivity combinatorial (HPC) system in accordance with some embodiments of the present invention.

FIG. 4 is a simplified schematic diagram illustrating a sputter processing chamber configured to perform combinatorial processing and full substrate processing in accordance with some embodiments of the present invention.

FIG. 5 is a simplified schematic diagram illustrating a sputter processing gun configured to perform combinatorial processing and full substrate processing before implementation of some embodiments of the present invention.

FIG. 6 is a simplified schematic diagram illustrating a sputter processing gun configured to perform combinatorial processing and full substrate processing in accordance with some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

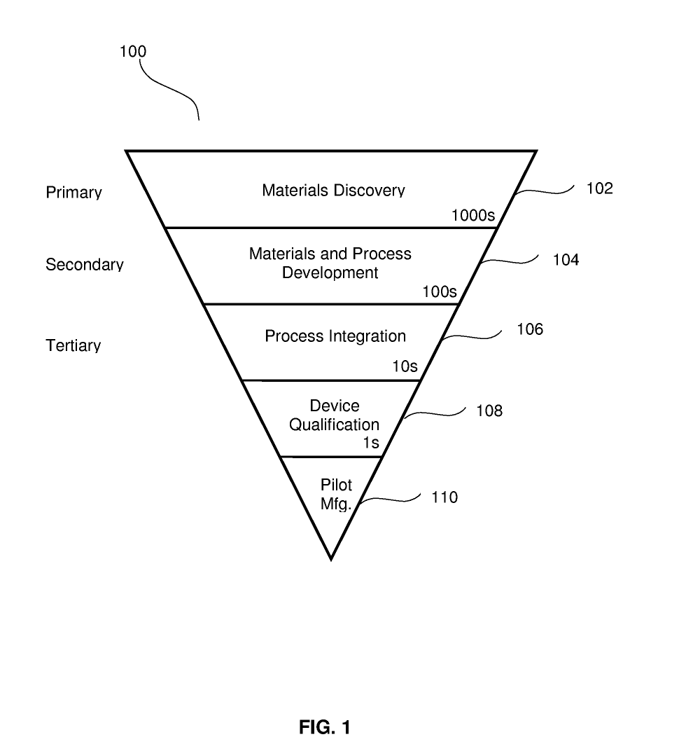

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor devices, TFPV modules, optoelectronic devices, etc. manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a semiconductor devices, TFPV modules, optoelectronic devices, etc. device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture semiconductor devices, TFPV modules, optoelectronic devices, etc. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor devices, TFPV modules, optoelectronic devices, etc. For example, such structures may include, but would not be limited to, contact layers, buffer layers, absorber layers, or any other series of layers or unit processes that create an intermediate structure found on semiconductor devices, TFPV modules, optoelectronic devices, etc. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

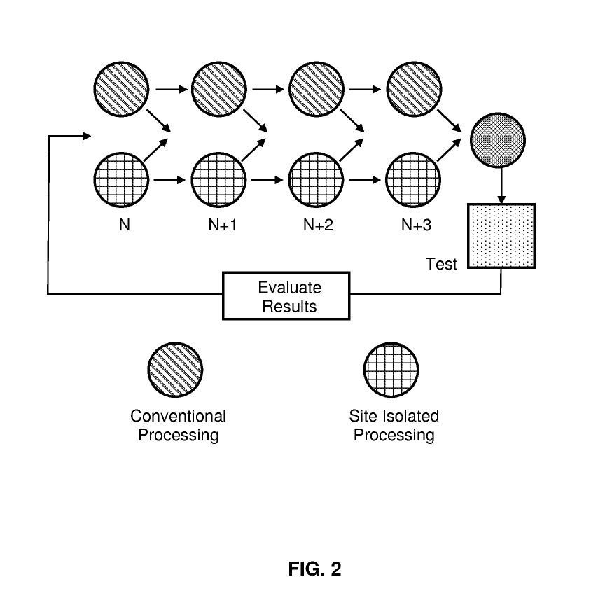

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor device, TFPV module, optoelectronic device, etc. manufacturing may be varied.

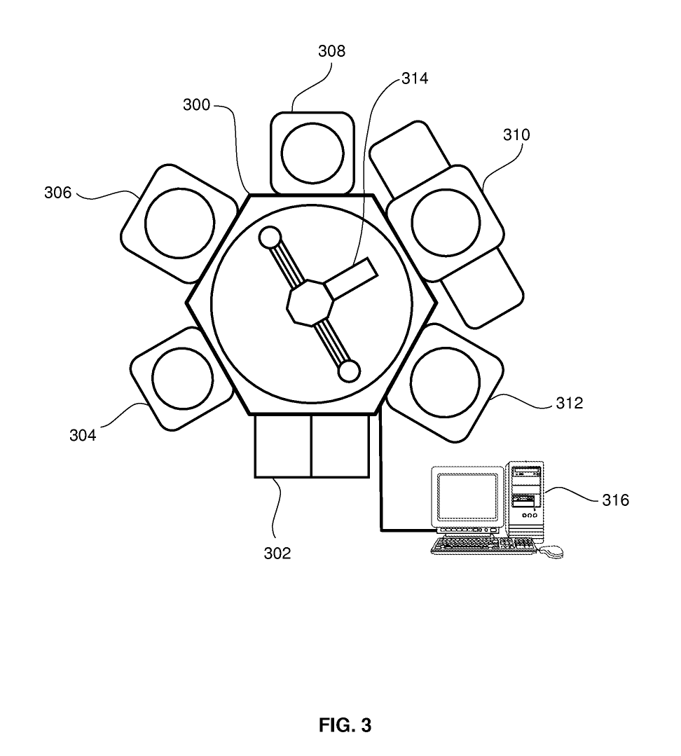

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. No. 11/672,478 filed Feb. 7, 2007, now U.S. Pat. No. 7,867,904 and claiming priority to U.S. Provisional Application No. 60/832,248 filed on Jul. 19, 2006, and U.S. application Ser. No. 11/672,473, filed Feb. 7, 2007 and claiming priority to U.S. Provisional Application No. 60/832,248 filed on Jul. 19, 2006, which are all herein incorporated by reference. With HPC system, a plurality of methods may be employed to deposit material upon a substrate employing combinatorial processes.

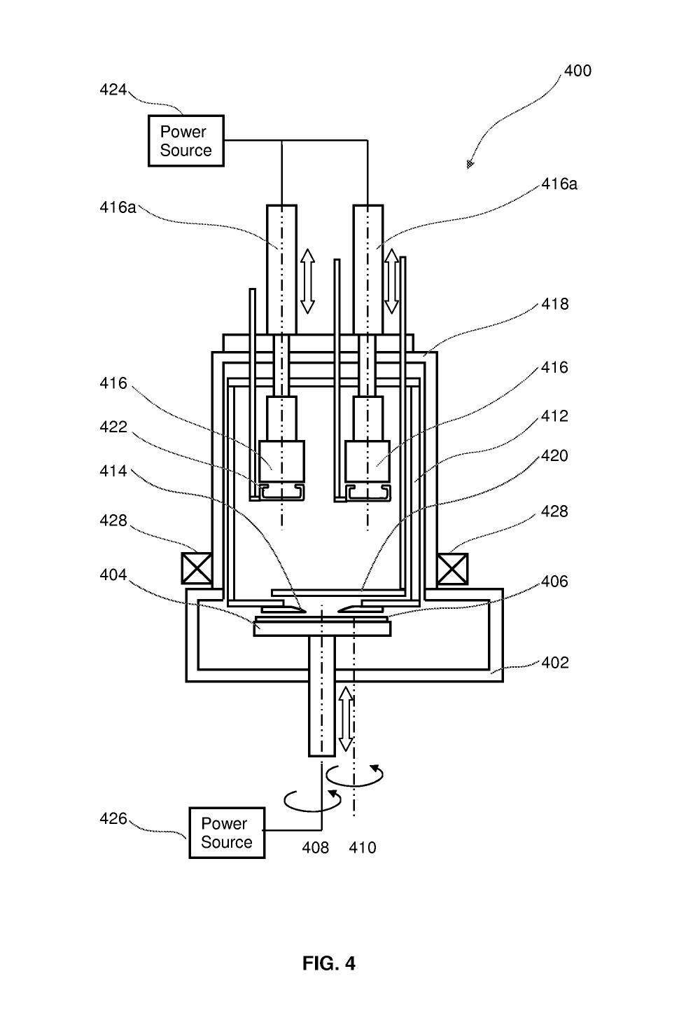

FIG. 4 is a simplified schematic diagram illustrating a sputter chamber configured to perform combinatorial processing and full substrate processing in accordance with some embodiments of the invention. Processing chamber, 400, includes a bottom chamber portion, 402, disposed under top chamber portion, 418. Within bottom portion, 402, substrate support, 404, is configured to hold a substrate, 406, disposed thereon and can be any known substrate support, including but not limited to a vacuum chuck, electrostatic chuck or other known mechanisms. Substrate support, 404, is capable of both rotating around its own central axis, 408 (referred to as “rotation” axis), and rotating around an exterior axis, 410, (referred to as “revolution” axis). Such dual rotary substrate support is central to combinatorial processing using site-isolated mechanisms. Other substrate supports, such as an XY table, can also be used for site-isolated deposition. In addition, substrate support, 404, may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source, 426, provides a bias power to substrate support, 404, and substrate, 406, and produces a negative bias voltage on substrate, 406. In some embodiments power source, 426, provides a radio frequency (RF) power sufficient to take advantage of the high metal ionization to improve step coverage of vias and trenches of patterned wafers. In some embodiments, the RF power supplied by power source, 426, is pulsed and synchronized with the pulsed power from power source, 424.

Substrate, 406, may be a conventional round 200 mm, 300 mm, or any other larger or smaller substrate/wafer size. In some embodiments, substrate, 406, may be a square, rectangular, or other shaped substrate. One skilled in the art will appreciate that substrate, 406, may be a blanket substrate, a coupon (e.g., partial wafer), or even a patterned substrate having predefined regions. In some embodiments, substrate, 406, may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion, 418, of chamber, 400, in FIG. 4 includes process kit shield, 412, which defines a confinement region over a radial portion of substrate, 406. Process kit shield, 412, is a sleeve having a base (optionally integrated with the shield) and an optional top within chamber, 400, that may be used to confine a plasma generated therein. The generated plasma will dislodge atoms from a target and the sputtered atoms will deposit on an exposed surface of substrate, 406, to combinatorial process regions of the substrate in some embodiments. In another embodiment, full wafer processing can be achieved by optimizing gun tilt angle and target-to-substrate spacing, and by using multiple process guns, 416. Process kit shield, 412, is capable of being moved in and out of chamber, 400, (i.e., the process kit shield is a replaceable insert). In another embodiment, process kit shield, 412, remains in the chamber for both the full substrate and combinatorial processing. Process kit shield, 412, includes an optional top portion, sidewalls and a base. In some embodiments, process kit shield, 412, is configured in a cylindrical shape, however, the process kit shield may be any suitable shape and is not limited to a cylindrical shape.

The base of process kit shield, 412, includes an aperture, 414, through which a surface of substrate, 406, is exposed for deposition or some other suitable semiconductor processing operations. Aperture shutter, 420, which is moveably disposed over the base of process kit shield, 412. Aperture shutter, 420, may slide across a bottom surface of the base of process kit shield, 412, in order to cover or expose aperture, 414, in some embodiments. In another embodiment, aperture shutter, 420, is controlled through an arm extension which moves the aperture shutter to expose or cover aperture, 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture, 414, may be a larger opening and aperture shutter, 420, may extend with that opening to either completely cover the aperture or place one or more fixed apertures within that opening for processing the defined regions. The dual rotary substrate support, 404, is central to the site-isolated mechanism, and allows any location of the substrate or wafer to be placed under the aperture, 414. Hence, the site-isolated deposition is possible at any location on the wafer/substrate.

A gun shutter, 422, may be included. Gun shutter, 422, functions to seal off a deposition gun when the deposition gun may not be used for the processing in some embodiments. For example, two process guns, 416, are illustrated in FIG. 4. Process guns, 416, are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter, 422, can be transitioned to cover and isolate the lifted process guns from the processing area defined within process kit shield, 412. In this manner, the process guns are isolated from certain processes when desired. It should be appreciated that gun shutter, 422, may be integrated with the top of the process kit shield, 412, to cover the opening as the process gun is lifted or individual gun shutter, 422, can be used for each target. In some embodiments, process guns, 416, are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion, 418, of chamber, 400, of FIG. 4 includes sidewalls and a top plate which house process kit shield, 412. Arm extensions, 416a, which are fixed to process guns, 416, may be attached to a suitable drive, (i.e., lead screw, worm gear, etc.), configured to vertically move process guns, 416, toward or away from a top plate of top chamber portion, 418. Arm extensions, 416a, may be pivotally affixed to process guns, 416, to enable the process guns to tilt relative to a vertical axis. In some embodiments, process guns, 416, tilt toward aperture, 414, when performing combinatorial processing and tilt toward a periphery of the substrate being processed when performing full substrate processing. It should be appreciated that process guns, 416, may tilt away from aperture, 414, when performing combinatorial processing in another embodiment. In yet another embodiment, arm extensions, 416a, are attached to a bellows that allows for the vertical movement and tilting of process guns, 416. Arm extensions, 416a, enable movement with four degrees of freedom in some embodiments. Where process kit shield, 412, is utilized, the aperture openings are configured to accommodate the tilting of the process guns. The amount of tilting of the process guns may be dependent on the process being performed in some embodiments.

Power source, 424, provides power for sputter guns, 416, whereas power source, 426, provides RF bias power to an electrostatic chuck. As mentioned above, the output of power source, 426, is synchronized with the output of power source, 424. It should be appreciated that power source, 424, may output a direct current (DC) power supply or a radio frequency (RF) power supply. In another embodiment the DC power is pulsed and the duty cycle is less than 30% on-time at maximum power in order to achieve a peak power of 10-15 kilowatts. Thus, the peak power for high metal ionization and high density plasma is achieved at a relatively low average power which will not cause any target overheating/cracking issues. It should be appreciated that the duty cycle and peak power levels are exemplary and not meant to be limiting as other ranges are possible and may be dependent on the material and/or process being performed.

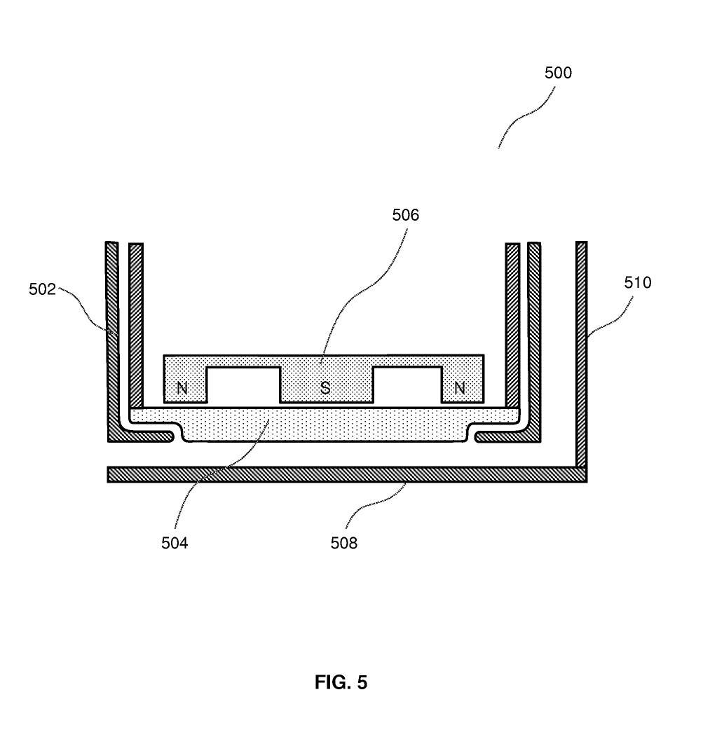

FIG. 5 is a simplified schematic diagram illustrating a sputter processing chamber configured to perform combinatorial processing and full substrate processing before implementation of some embodiments of the present invention. FIG. 5 illustrates a portion of a sputter gun, 500, that would be part of the sputter gun, 416, in FIG. 4. Illustrated in FIG. 5 is a grounded shield, 502 surrounding the exterior of the target, 504, and magnetron, 506, assembly. Systems with the configuration as described in relation to FIG. 4 had a gun shutter (422 in FIG. 4) for each sputter gun. This is illustrated as element, 508, in FIG. 5. The gun shutter was rotated in front of the sputter gun using shaft 510. Although the gun shutter illustrated in FIG. 5 was effective for protecting the sputter gun from receiving deposition from other sputter sources within the chamber, it was not useful as a shield during target burn-in operations. That is, the chamber required an additional burn-in shield or a burn-in substrate to condition the target.

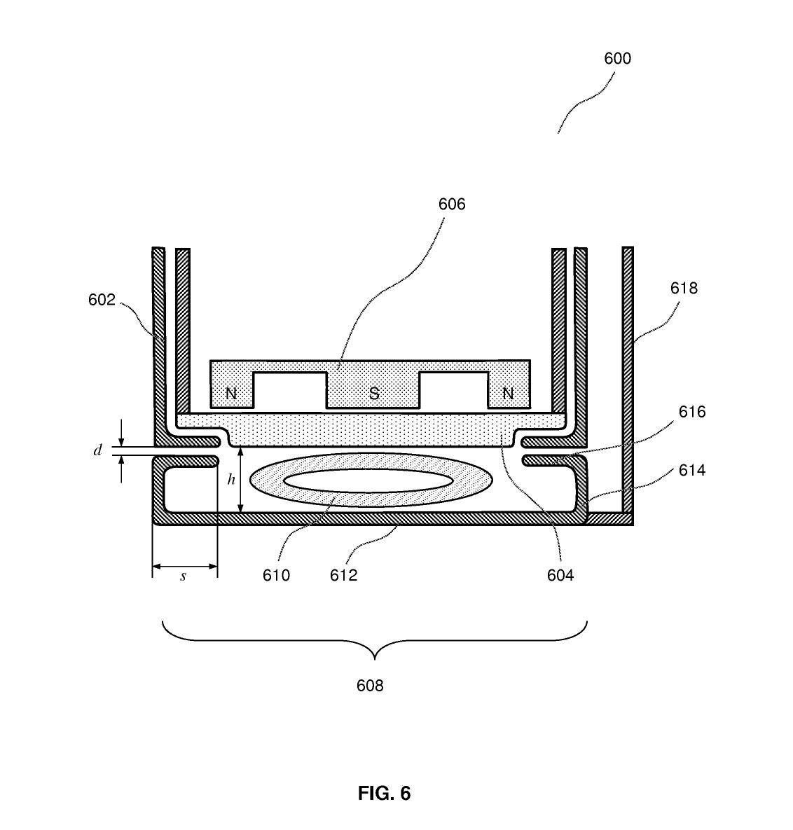

FIG. 6 is a simplified schematic diagram illustrating a sputter processing chamber configured to perform combinatorial processing and full substrate processing in accordance with some embodiments of the present invention. FIG. 6 illustrates a portion of a sputter gun, 600, that would be part of the sputter gun, 416, in FIG. 4. Illustrated in FIG. 6 is a grounded shield, 602, surrounding the exterior of the target, 604, and magnetron, 606, assembly. Systems with the configuration as described in relation to FIG. 4 had a gun shutter (422 in FIG. 4) for each sputter gun. Illustrated in FIG. 6 is a gun shutter according to some embodiments of the present invention. The gun shutter, 608, illustrated in FIG. 6 provides a greater distance, h, between the face of the target and the shutter. The distance may be between about 10 mm and about 50 mm. This greater distance allows a stable plasma, 610, to be maintained between the target and the gun shutter. In contrast, the distance between the target surface and the gun shutter in FIG. 5 is smaller (i.e. distance of about 2-10 mm). The smaller distance would prevent plasma from being ignited or require a higher pressure to ignite a plasma between the target face and the gun shutter and the plasma would not be stable. Gun shutter, 608, comprises a bottom plate, 612, and a side wall, 614. The bottom plate, 612, has a peripheral edge and a central axis. The central axis of the bottom plate is aligned with the central axis of the target. The side wall, 614, is attached at its lower edge to the peripheral edge of the bottom plate, 612. The bottom plate and side wall form a complete enclosure around the face of the target. The side wall, 614, can have a smaller dimension at where it meets with the bottom plate, 612, resulting in a conically-shaped gun shutter, 608. Gun shutter, 608, further comprises a gun shutter lip, 616, that aligns with a similar lip on grounded shield, 602. The gun shutter lip, 616, is formed at the upper edge of the side wall, 614. The gun shutter lip extends inward, toward the central axis of the bottom plate. The length, s, of the gun shutter lip, 616, in the direction toward the central axis of the bottom plate may be between about 10 mm and about 50 mm. The alignment of the gun shutter lip and the grounded shield lip forms a gap, d, between the gun shutter and the shield. The gap may be between about 0.5 mm and about 5 mm. The gap is effective at preventing sputtered material from exiting the gun shutter when a plasma is sustained within the gun shutter, or entering onto the target surface of the concerned gun when the sputtered materials are from other guns in the deposition chamber. Similar to the gun shutter in FIG. 5, the gun shutter in FIG. 6 may be rotated in front of the sputter gun using shaft, 618. The gun shutter may be formed from any metal as is typically used in sputter chambers. Examples include stainless steel, stainless steel alloys, aluminum, etc. Those skilled in the art will understand that ferromagnetic materials are to be avoided.

The gun shutter illustrated in FIG. 6 exhibits a number of benefits. The increased distance between the face of the target and the gun shutter allows a plasma to be ignited and sustained at typical sputtering pressures. This allows the gun shutter to be used as a shield for the burn-in and conditioning of the target. Therefore, the aperture shutter, 420, from FIG. 4 is not required. This simplifies the design of the sputtering chamber and allows a more compact and cost effective design. Furthermore, the gun shutter is more effective at preventing sputtered material from other sputter guns present in the chamber from contaminating the sputter gun due to the small gap formed between the grounded shield lip and the gun shutter lip. Additionally, the gun shutter is easily removed to be cleaned or replaced and enhances the serviceability of the sputtering chamber.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A shutter for a sputter gun comprising:
a bottom plate having a planar surface, a peripheral edge, and a central axis, wherein the central axis is perpendicular to the planar surface;
a side wall having an upper edge and a lower edge, wherein the lower edge of the side wall is attached at the peripheral edge of the bottom plate; and
a first lip formed at the upper edge of the side wall, wherein the lip extends toward the central axis of the bottom plate.

2. The shutter of claim 1 wherein the first lip is further aligned with a second lip disposed on a grounded shield to form a gap.

3. The shutter of claim 2 wherein the gap is between about 0.5 mm and about 5 mm.

4. The shutter of claim 1 wherein length the first lip in a direction toward the central axis of the bottom plate is between about 10 mm and about 50 mm.

5. The shutter of claim 1 wherein a distance from the bottom plate to a target face is between about 10 mm and about 50 mm.

6. The shutter of claim 1 wherein the shutter is further connected to a shaft, wherein the shaft is operable to rotate the shutter in front of a sputter target.

7. A sputter gun comprising:
a magnetron;
a target disposed adjacent to the magnetron, the target having a central axis and a periphery;
a grounded shield having a lower edge, the grounded shield disposed around the periphery of the target, wherein the grounded shield further comprises a first lip formed at the lower edge of the grounded shield, wherein the first lip extends in a direction toward the central axis of the target; and
a shutter, the shutter comprising:
a bottom plate having a planar surface, a peripheral edge, and a central axis, wherein the central axis is perpendicular to the planar surface;
a side wall having an upper edge and a lower edge, wherein the lower edge of the side wall is attached at the peripheral edge of the bottom plate; and
a second lip formed at the upper edge of the side wall, wherein the lip extends toward the central axis of the bottom plate.

8. The sputter gun of claim 1 wherein the first lip of the grounded shield is aligned with the second lip of the shutter to form a gap.

9. The sputter gun of claim 8 wherein the gap is between about 0.5 mm and about 5 mm.

10. The sputter gun of claim 1 wherein length the second lip in a direction toward the central axis of the bottom plate is between about 10 mm and about 50 mm.

11. The sputter gun of claim 1 wherein a distance from the bottom plate to a target face is between about 10 mm and about 50 mm.

12. The sputter gun of claim 1 wherein the shutter is further connected to a shaft, wherein the shaft is operable to rotate the shutter in front of a sputter target.
